(19) United States
(12) Patent Application Publication
(10) Pub. No.: US 2012/0112867 A1
(43) Pub. Date: May 10, 2012

(54) CHOKE MODULE HAVING IMPROVED ARRANGEMENT OF MAGNETIC UNIT

(75) Inventors: John CHOW, Saratoga, CA (US); Li-Chun WU, New Taipei (TW); Yueh-Shan SHIH, New Taipei (TW); Jie ZHANG, Kunshan (CN); Jian-She HU, Kunshan (CN); Lin-Zhong GE, Kunshan (CN)

(73) Assignee: HON HAI PRECISION INDUSTRY CO., LTD., New Taipei (TW)

(21) Appl. No.: 13/290,331

(22) Filed: Nov. 7, 2011

(30) Foreign Application Priority Data
Nov. 5, 2010 (CN) 201020593353.4

(51) Int. Cl. H01F 27/29

(52) U.S. Cl. 336/192

(57) ABSTRACT

A choke module (100) for connecting with a mother board includes a housing (1), a magnetic unit (2) and a number of terminals (3). The magnetic unit includes a paddle board (21) attached to the housing and having a number of conductive pads 9212) and conductive sections (211), a number of SMDs (Surface Mount Devices 22) surface mounted on the paddle board, and a number of magnetic components (23) each having a magnetic core (231) stacked on the corresponding SMD along a vertical direction and a plurality of wires (232) winding around the magnetic core and soldered on the conductive pads. The number terminals are electrically connected with the conductive sections and secured to the housing for connecting with the mother board.

### BACKGROUND OF THE INVENTION

1. Field of the Invention

The present invention relates to a choke module, and more particularly to a choke module having an improved magnetic unit for application in high speed signal transmission systems.

2. Description of Related Art

U.S. Patent Application Publication No. 2011/0122589 published on May 26, 2011 discloses a choke module comprising a housing defining a cavity, a circuit board having a first surface facing the cavity, a plurality of magnetic components, and two rows of first terminals mounted in the circuit board. The magnetic components comprise a row of embedded transformers and a row of SMD (Surface Mount Device) elements soldered on the circuit board. The row of SMD elements have to be provided beside the row of embedded transformers along a width direction of the circuit board for reducing interference.

The circuit board has to be formed with a sufficient width to mount the two rows of magnetic components in juxtaposed manner along the width direction.

Hence, a choke module having improved arrangement of magnetic unit is desired.

### SUMMARY OF THE INVENTION

Accordingly, an object of the present invention is to provide a choke module having an improved magnetic unit arrangement which occupies less space.

In order to achieve the object set forth, a choke module for connecting with a mother board comprises a housing, a magnetic unit and a plurality of terminals. The magnetic unit includes a paddle board attached to the housing and having a plurality of conductive pads and conductive sections, a plurality of SMDs (Surface Mount Devices) surface mounted on the paddle board, and a plurality of magnetic components each having a magnetic core stacked on the corresponding SMD along a vertical direction and a plurality of wires winding around the magnetic core and soldered on the conductive pads. The plurality of terminals are electrically connected with the conductive sections and secured to the housing for connecting with the mother board.

The magnetic components are vertically stacked on the SMDs to occupy less space of the paddle board at a width direction. Therefore, it is facilitate to comply with the miniature trend.

Other objects, advantages and novel features of the invention will become more apparent from the following detailed description when taken in conjunction with the accompanying drawings.

### BRIEF DESCRIPTION OF THE DRAWINGS

FIG. 1 is an assembled perspective view showing a choke module in accordance with the present invention;

FIG. 2 is an assembled perspective view similar to FIG. 1, taken from another aspect;

FIG. 3 is a partially exploded view showing the choke module;

FIG. 4 is a partially exploded view similar to FIG. 3, taken from another aspect;

FIG. 5 is an exploded view showing the choke module; and

FIG. 6 is a cross-sectional view showing the choke module, taken along line 6-6 of FIG. 1.

### DETAILED DESCRIPTION OF THE PREFERRED EMBODIMENT

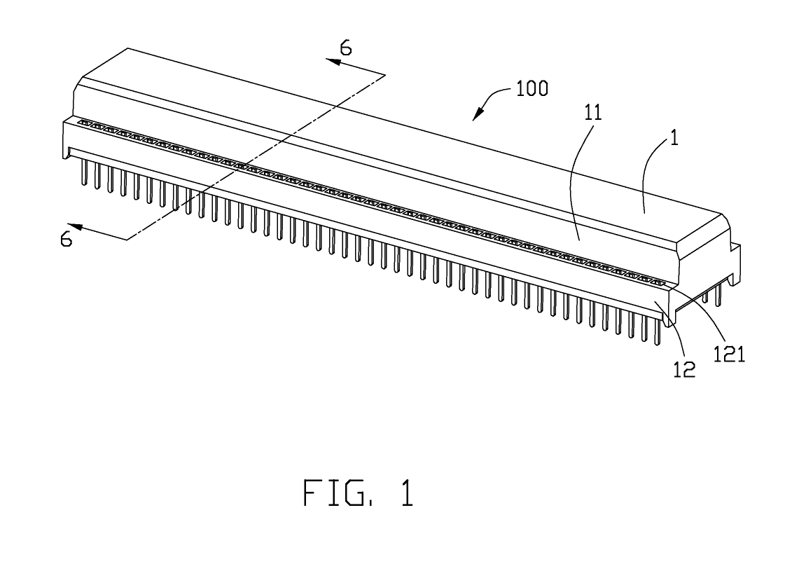

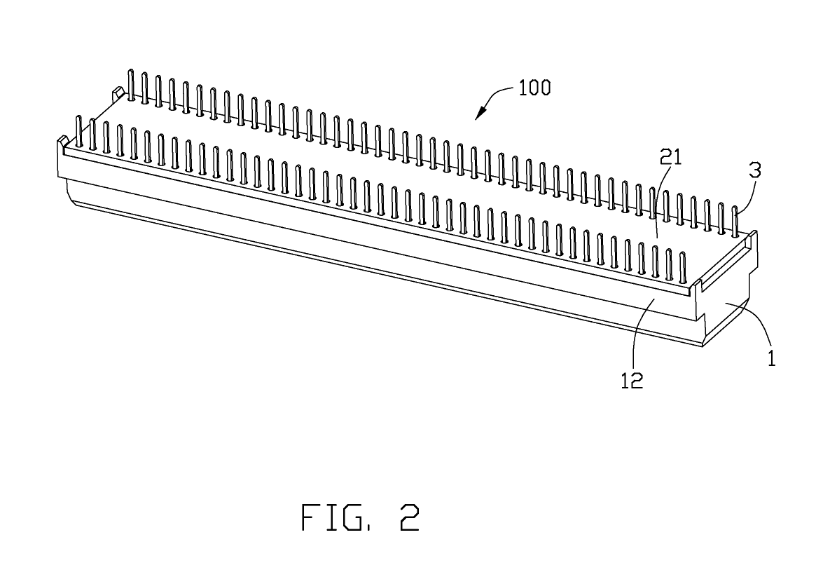

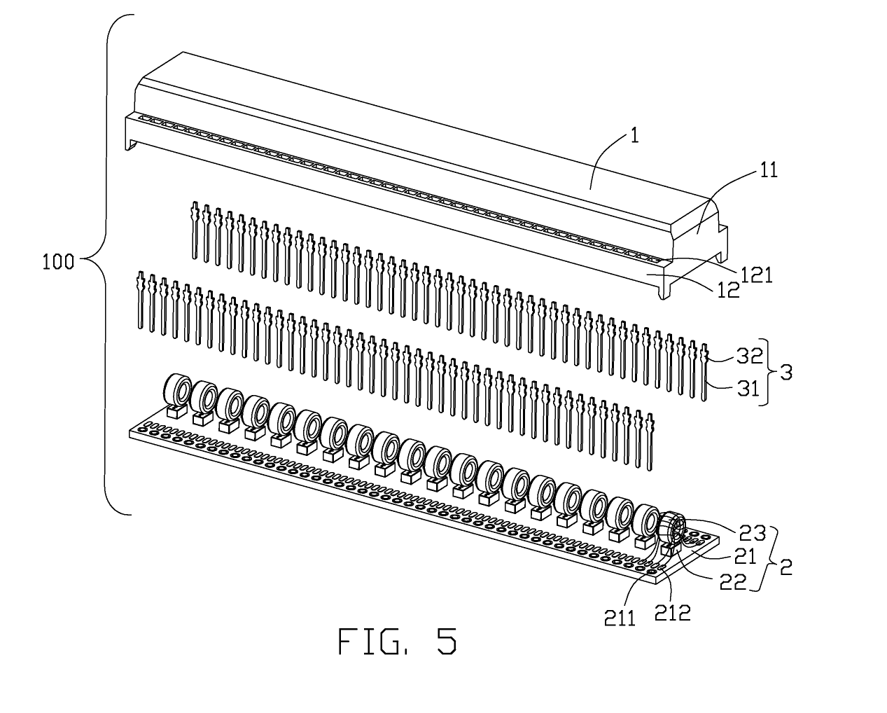

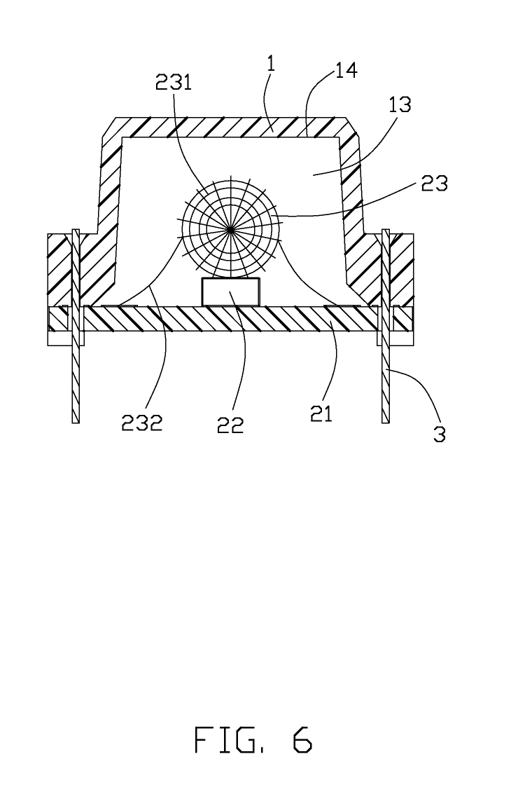

Reference will now be made in detail to the preferred embodiment of the present invention. Referring to FIGS. 1-6, a choke module 100 mounted on a mother board (not shown) comprises a housing 1 defining a cavity 13, a magnetic module 2 and two rows of terminals 3 mounted in the housing 1.

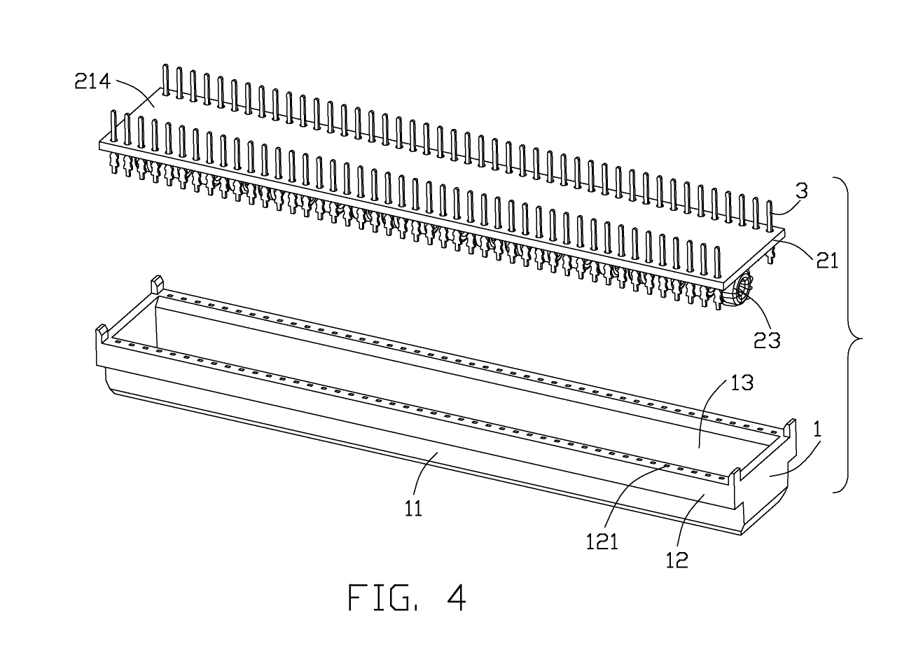

Referring to FIGS. 4-6, the housing 1 comprises a body portion 11 having a top face 14 facing the cavity 13, a pair of side walls 12 disposed at opposite sides of the body portion 11. Each side wall 12 defines a row of securing holes 121 extending therethrough along an up-to-bottom direction.

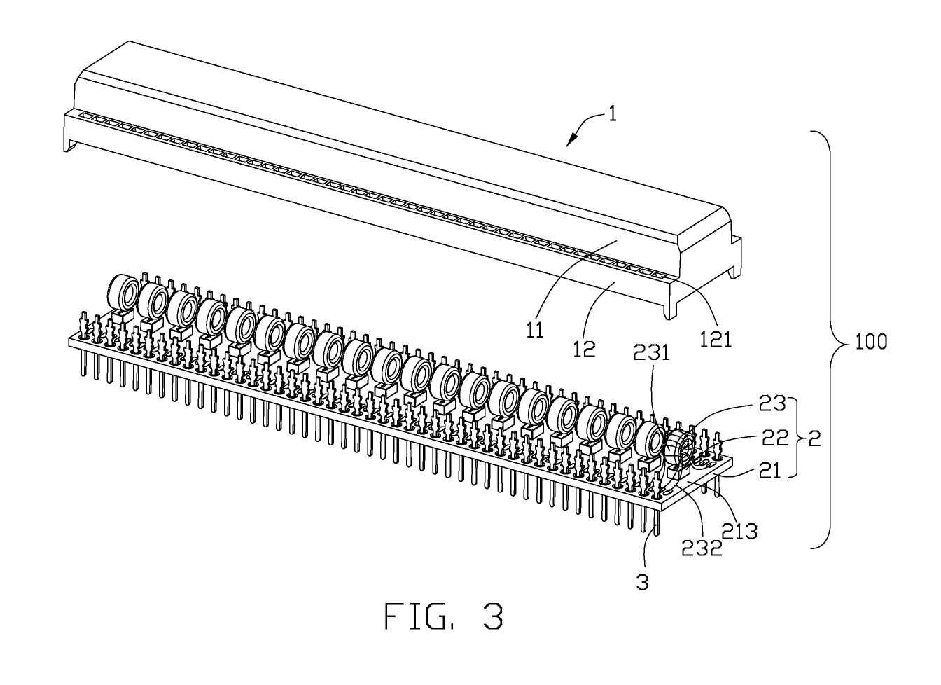

Referring to FIGS. 3-6, the magnetic unit 2 comprises a paddle board 21 defines two rows of conductive holes 211. The paddle board 21 has opposite first face 213 and second face 214, and two rows of conductive pads 212 between the two rows of conductive holes 211 and provided on the first face 213. The magnetic unit 2 further comprises a plurality of SMDs (Surface Mount Devices) 22 and a plurality of magnetic components 23 each having a magnetic core 231 and a plurality of wires 232 winding around the magnetic core 231. The SMDs 22 are common mode chokes and the magnetic components 23 are transformers in this preferred embodiment.

Referring to FIG. 3, each terminal 3 includes a securing portion 32 and an inserting portion 31 extending downwardly from the securing portion 32.

Referring to FIGS. 3-6, in assembling of the magnetic unit 2, the plurality of SMDs 22 are surface mounted on the first face 213 of paddle board 21 in a row between two rows of conductive pads 212. The plurality of magnetic components 23 are mounted on the paddle board 21, with each magnetic core 231 stacked on the corresponding SMD 22 along a vertical direction and the wires 232 soldered on the two conductive pads 212 of the two rows.

Referring to FIGS. 1-6, in assembling of the choke module 1, the paddle board 21 is attached to the cavity 13, with the first face 213 facing the cavity 13 and the SMDs 22 and the magnetic components 23 received in the cavity 13. The top face 14 of the housing 1, the paddle board 21 are parallel with the mother board. The conductive holes 211 of the paddle board 21 are respectively aligned with corresponding securing holes 121. The securing portion 32 of each terminal 3 is secured in the securing hole 121 and the inserting portion 31 is inserted through the conductive hole 211 for connecting with the mother board.

The paddle board 21 could be designed into a smaller width to locate the vertically staked SMDs 22 and magnetic components 23. Therefore, it is facilitate to comply with the miniature trend.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A choke module for connecting with a mother board, comprising:
a housing;
a magnetic unit including a paddle board attached to the housing and having a plurality of conductive pads and conductive sections, a plurality of SMDs (Surface Mount Devices) surface mounted on the paddle board, and a plurality of magnetic components each having a magnetic core stacked on a corresponding SMD along a vertical direction and a plurality of wires winding around the magnetic core and soldered on the conductive pads; and
a plurality of terminals electrically connected with the conductive sections and secured to the housing for connecting with the mother board.

2. The choke module as claimed in claim 1, wherein said SMDs are common mode chokes, and the magnetic components are transformers.

3. The choke module as claimed in claim 1, wherein said housing defines a cavity, said paddle board having a first face facing the cavity, said SMDs and magnetic components being mounted at the first face of the paddle board in one row and received in the cavity.

4. The choke module as claimed in claim 3, wherein said housing includes a body portion having a top face facing the cavity, and said top face of the housing and the paddle board are parallel with the mother board.

5. The choke module as claimed in claim 3, wherein said plurality of conductive sections are formed into two rows of conductive holes for insertion of the terminals.

6. The choke module as claimed in claim 5, wherein said housing comprises a pair of side walls disposed at opposite sides of the body portion, each side wall defining a securing hole aligned with a corresponding conductive hole, each terminal having a securing portion secured in the securing hole and an inserting portion inserted through the conductive hole.

7. The choke module as claimed in claim 5, wherein said plurality of conductive pads are formed into two rows of conductive pads respectively disposed at opposite sides of the SMDs and between the two rows of conductive holes.

8. A choke module for mounting to a mother board, comprising:
a housing defining a downwardly facing receiving cavity in a vertical direction;
a magnetic unit assembled to the housing and including a paddle board, a plurality of common mode chokes and magnetic components arranged with pairs mounted to the paddle board and commonly received in the receiving cavity under condition that the magnetic component is stacked upon the corresponding common mode choke in said vertical direction in each pair; and
a plurality of terminals mounted to the paddle board and located on an outer side with regard to the paired chokes and magnetic components; wherein
a plurality of wires are electrically connected between the corresponding magnetic components and terminals, respectively.

9. The choke module as claimed in claim 8, wherein the wires are mechanically connected to the corresponding magnetic components while are mechanically connected to corresponding conductive pads on the paddle board for electrically connecting to the corresponding terminals, respectively.

10. The choke module as claimed in claim 9, wherein the conductive pads are located inside of the corresponding terminals.
